(19) United States
(12) Patent Application Publication
(10) Pub. No.: US 2023/0290784 A1
(43) Pub. Date: Sep. 14, 2023

(54) INTEGRATED CIRCUIT INCLUDING ACTIVE PATTERN HAVING VARIABLE WIDTH AND METHOD OF DESIGNING THE SAME

(71) Applicant: Samsung Electronics Co., Ltd., Suwon-si (KR)

(72) Inventors: Jungho Do, Suwon-si (KR); Jisu Yu, Suwon-si (KR); Hyeongyu You, Suwon-si (KR); Yunkyeong Jang, Suwon-si (KR); Minjae Jeong, Suwon-si (KR)

(21) Appl. No.: 18/175,696

(22) Filed: Feb. 28, 2023

(30) Foreign Application Priority Data
Mar. 10, 2022 (KR) 10-2022-0030331
Jun. 22, 2022 (KR) 10-2022-0076380

(51) Int. Cl. H01L 27/118; H01L 27/02

(52) U.S. Cl. CPC H01L 27/11807; H01L 27/0207; H01L 2027/11809

(57) ABSTRACT

An integrated circuit may include a first active pattern group extending in a first direction in a first row and including a plurality of first active patterns overlapping each other in the first direction, the first row extending in the first direction, and a plurality of gate electrodes extending in a second direction perpendicular to the first direction in the first row. The plurality of first active patterns may include any two first active patterns that are adjacent to each other in the first direction, the two first active patterns have first and second widths in the second direction, respectively, and the first and second widths are identical or are different by a first offset or a second offset.

### CROSS-REFERENCE TO RELATED APPLICATIONS

This application is based on and claims priority under 35 U.S.C. §119 to Korean Patent Application Nos. 10-2022-0030331, filed on Mar. 10, 2022, and 10-2022-0076380, filed on Jun. 22, 2022, in the Korean Intellectual Property Office, the disclosures of which are incorporated by reference herein in their entireties.

### BACKGROUND

The inventive concept relates to an integrated circuit, and more particularly, to an integrated circuit including an active pattern having a variable width, and a method of designing the same.

Devices having various structures have been developed, and those devices may have unique characteristics, respectively. New devices may be formed by new processes (e.g., sub-processes), and accordingly, new design rules may be beneficial to design an integrated circuit including the new devices.

### SUMMARY

The inventive concept provides an integrated circuit including an active pattern having a variable width and a method of designing the same.

According to an aspect of the inventive concept, there is provided an integrated circuit including a first active pattern group extending in a first direction in a first row and including a plurality of first active patterns overlapping each other in the first direction, the first row extending in the first direction, and a plurality of gate electrodes extending in a second direction perpendicular to the first direction in the first row. The plurality of first active patterns may include any two first active patterns that are adjacent to each other in the first direction, the two first active patterns have first and second widths in the second direction, respectively, and the first and second widths are identical or are different by a first offset or a second offset. According to an aspect of the inventive concept, there is provided an integrated circuit including a plurality of functional cells arranged in a first row extending in a first direction, wherein each of the plurality of functional cells arranged in the first row may include a first active pattern extending in the first direction, and at least one first gate electrode extending in a second direction perpendicular to the first direction. The plurality of first functional cells may include two first functional cells that are adjacent to each other and may include two first active patterns, respectively, and the two first active patterns may overlap each other in the first direction, may have respective widths in the second direction, and the widths of the two first active patterns may be identical or are different by a first offset or a second offset.

According to an aspect of the inventive concept, there is provided an integrated circuit including a plurality of cells, a first pattern and a second pattern extending in a first direction and adjacent to each other to supply power to first cells among a plurality of cells, a plurality of first active patterns extending in the first direction between the first pattern and the second pattern and overlapping each other in the first direction, and a plurality of first gate electrodes extending in a second direction perpendicular to the first direction between the first pattern and the second pattern, wherein two first active patterns adjacent to each other in the first direction among the plurality of first active patterns may have the same width in the second direction, or have widths in the second direction that are different by a first offset or a second offset.

### BRIEF DESCRIPTION OF DRAWINGS

Embodiments of the inventive concept will be more clearly understood from the following detailed description taken in conjunction with the accompanying drawings in which:

FIGS. 1A and 1B are perspective views of devices according to example embodiments;

FIGS. 2A and 2B are plan views illustrating layouts of an integrated circuit according to example embodiments;

FIGS. 3A and 3B are plan views illustrating layouts of an integrated circuit according to example embodiments;

FIG. 4 is a plan view illustrating a layout of a cell according to an example embodiment;

FIG. 5 is a plan view illustrating a layout of an integrated circuit according to an example embodiment;

FIGS. 6A, 6B, 6C, 6D, 6E and 6F are plan views illustrating layouts of an integrated circuit according to example embodiments;

FIG. 7 is a flowchart illustrating a method of manufacturing an integrated circuit, according to an example embodiment;

FIG. 8 is a block diagram illustrating a system-on-chip according to an example embodiment; and

FIG. 9 is a block diagram illustrating a computing system including a memory for storing a program, according to an example embodiment.

### DETAILED DESCRIPTION

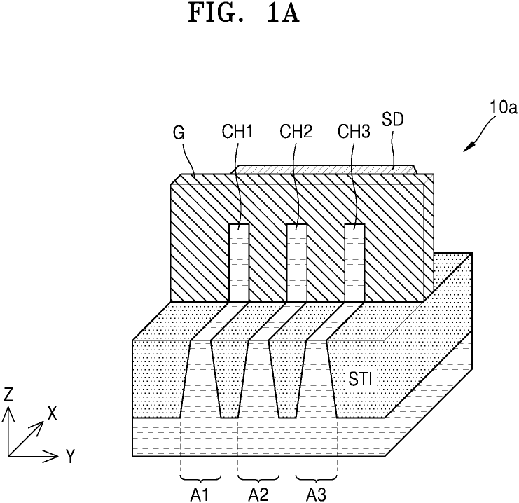

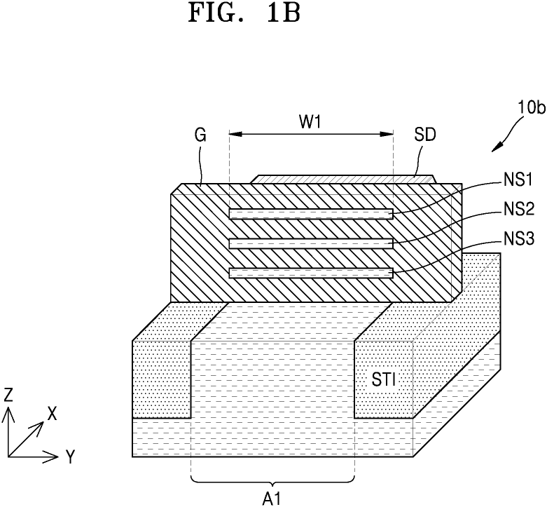

FIGS. 1A and 1B are perspective views of devices according to example embodiments. For example, FIG. 1A illustrates a fin field effect transistor (FinFET) 10a, and FIG. 1B illustrates a gate-all-round field effect transistor (GAAFET) 10b. For convenience of illustration, FIGS. 1A and 1B illustrate a state in which one of two source/drain regions has been removed.

Herein, an X-axis direction and a Y-axis direction may be referred to as a first direction (also referred to as a first horizontal direction) and a second direction (also referred to as a second horizontal direction), respectively, and a Z-axis direction may be referred to as a vertical direction or a third direction. A plane with an X-axis and a Y-axis may be referred to as a horizontal plane, a component arranged in the +Z direction relative to other components may be referred to as a component above the other components, and a component arranged in the -Z direction relative to other components may be referred to a component below the other components. In addition, the area of a component may refer to the size occupied by the component in a plane parallel to the horizontal plane, and the width of the component may refer to the length in a direction that is perpendicular to the direction in which the component extends (e.g., extends longitudinally). The surface exposed in the +Z direction may be referred to as a top surface or an upper surface, the surface exposed in the -Z direction may be referred to as a bottom surface or a lower surface, and the surface exposed in the ±X direction or the ±Y direction may be referred to as a side surface. In the drawings, only some layers may be illustrated for convenience of illustration, and in order to indicate a connection between an upper pattern and a lower pattern, a via may be displayed despite being positioned below the upper pattern. In addition, a pattern made of a conductive material, such as a pattern of a wiring layer, may be referred to as a conductive pattern or may be simply referred to as a pattern.

The integrated circuit may be manufactured by a semiconductor process and may include a plurality of devices. For example, the integrated circuit may include an active device, such as a transistor, and/or a passive device, such as a capacitor. The semiconductor process may include a series of sub-processes for forming a transistor having a predefined structure. For example, the FinFET 10a and the GAAFET 10b may be formed by a semiconductor process. In some embodiments, the semiconductor process may include sub-processes for forming a transistor having a structure different from those of the FinFET 10a and the GAAFET 10b. For example, nanosheets for the P-type transistor and nanosheets for the N-type transistor may be separated by dielectric walls, thereby forming, by a semiconductor process, a ForkFET having a structure of the N-type transistor and the P-type transistor, which are adjacent to each other. In addition, a bipolar junction transistor as well as a field effect transistor (FET), such as a complementary FET (CFET), a negative FET (NCFET), a carbon nanotube (CNT) FET and the like may be formed by a semiconductor process.

Referring to FIG. 1A, the FinFET 10a may be formed by first to third active patterns A1 to A3, which have a fin shape extending in the X-axis direction between shallow trench isolations (STIs), and a gate electrode G extending in the Y-axis direction. A source/drain region SD may be formed at either side of the gate electrode G, and first to third channels CH1 to CH3 respectively corresponding to the first to third active patterns A1 to A3 may be formed between the source/drain regions SD. The first to third channels CH1 to CH3 may overlap the gate electrode G in the Y-axis and Z-axis directions, and an insulating layer may be formed between the gate electrodes G and each of the first to third channels CH1 to CH3. In some embodiments, the source/drain region SD may be configured by three portions respectively corresponding to the first to third active patterns A1 to A3, unlike from those shown in FIG. 1A. As used herein, “an element A extends in a direction X” (or similar language) may mean that the element A extends longitudinally in the direction X. Further, as used herein, “an element A overlapping an element B in a direction X” (or similar language) means that there is at least one line that extends in the direction X and intersects both the elements A and B.

The effective channel width of the FinFET 10a may depend on the number of active patterns, and thus the FinFET 10a may have a current driving capability corresponding to the number of active patterns. For example, the FinFET including one or two channels may have a lower current driving capability and power consumption than the FinFET 10a of FIG. 1A. In addition, the FinFET including more than three channels may have higher current driving capability and power consumption than the FinFET 10a of FIG. 1A. The integrated circuit may include FinFETs including various numbers of channels to optimize performance and efficiency.

Referring to FIG. 1B, the GAAFET 10b may be formed by an active pattern A1 extending in the X-axis direction and a gate electrode G extending in the Y-axis direction. A source/drain region SD may be formed at either side of the gate electrode G, and first to third nanosheets NS 1 to NS3 that are spaced apart from each other in the Z-axis direction and extend in the X-axis direction, while having a first width W1, may form channels between the source/drain regions SDs. As shown in FIG. 1B, the GAAFET 10b including the nanosheet may be referred to as a multi-bridge channel field effect transistor (MBCFET). The first to third nanosheets may overlap the gate electrode G in the Y-axis and Z-axis directions, and an insulating layer may be formed between the gate electrodes G and each of the first to third nanosheets.

The effective channel width of the GAAFET 10b may depend on the number and width of the nanosheets, and thus the GAAFET 10b may have a current driving capability corresponding to the number and width of the nanosheets. For example, the GAAFET including one or two nanosheets or nanosheets having a width less than the first width W1 may have lower current driving capability and power consumption than the GAAFET 10b of FIG. 1B. In addition, the GAAFET including more than three nanosheets or nanosheets having a width greater than the first width W1 may have higher current driving capability and power consumption than the GAAFET 10b of FIG. 1B. The integrated circuit may include GAAFETs including nanosheets of various numbers and widths to optimize performance and efficiency.

The transition of the active pattern may refer to a change in the number and/or width of the active patterns in devices adjacent to each other. The FinFET 10a may realize transition of the active pattern by adjusting the number of channels (or the number of fins), while the GAAFET 10b may realize transition of the active pattern by adjusting the first width W1 of the nanosheet, and thus the GAAFET 10b may support devices having more various characteristics than the FinFET 10a.

As the size of the device decreases for high integration, difficulty of the semiconductor process may increase and transition of the active pattern may be limited by the semiconductor process. For example, when a large transition of an active pattern occurs, for example, when a structure in which the width of a nanosheet is greatly reduced or greatly increased in an integrated circuit is designed, the semiconductor process may not easily implement the designed structure. Accordingly, when the transition of the active pattern is large, the yield of the integrated circuit may be reduced, or the area of the integrated circuit may be increased due to a space (e.g., a diffusion break) for the transition of the active pattern.

As described with reference to the drawings below, the integrated circuit may be designed in consideration of a semiconductor process, thereby reducing time and cost required to design the integrated circuit and improving yield of the integrated circuit. In addition, the integrated circuit may have high reliability, and accordingly, the reliability of applications including the integrated circuit may be improved. Furthermore, integrated circuits with high reliability may be easily designed, thereby significantly reducing the time-to-market period of integrated circuits. Hereinafter, GAAFET, that is, MBCFET, will be mainly described as an example of the device, but it is noted that embodiments of the inventive concept are not limited thereto. In addition, although the transition of the active pattern generated by changing the widths of the nanosheets will be mainly described, it is noted that the transition of the active pattern may occur by changing the number of nanosheets as described above.

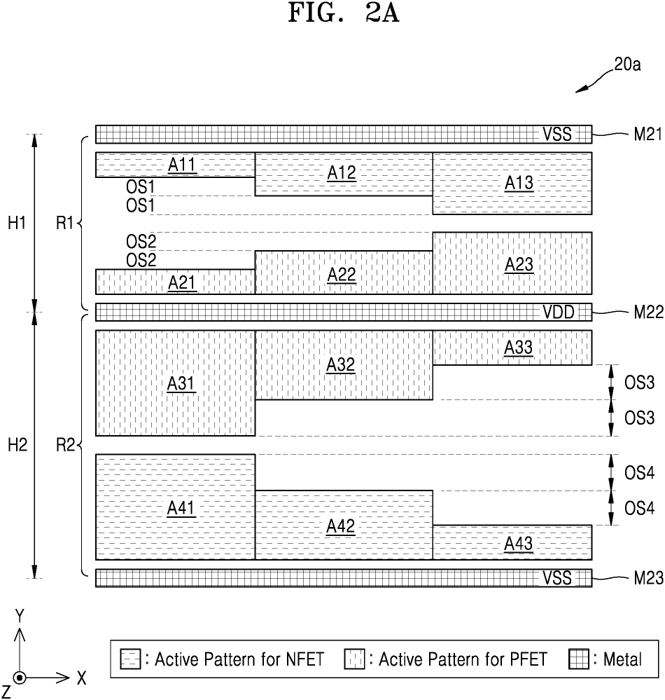

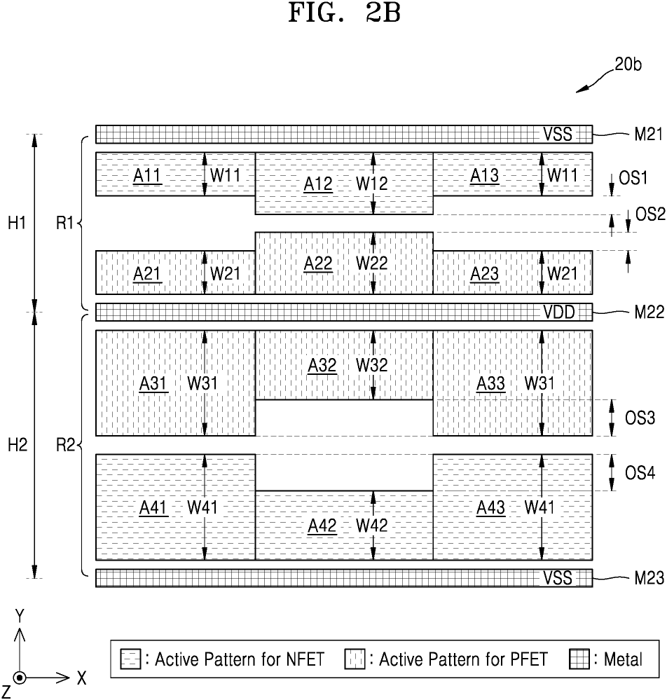

FIGS. 2A and 2B are plan views illustrating layouts of an integrated circuit according to example embodiments. Hereinbelow, the redundant description of FIGS. 2A and 2B will be omitted.

Referring to FIG. 2A, the integrated circuit may include a plurality of standard cells. A standard cell is a unit of layout included in an integrated circuit, and may be simply referred to as a cell. The cell may include a transistor and may be designed to perform a predefined function. In the integrated circuit, cells may be aligned and arranged in rows. For example, in FIG. 2A, a first row R1 and a second row R2 may extend in the X-axis direction, and the cells may be arranged in the first row R1 and/or second row R2. A cell arranged in one row may be referred to as a single height cell, and a cell arranged in two or more consecutive rows may be referred to as a multi-height cell. The single height cells arranged in the first row R1 may have a first height H1 in the Y-axis direction, the single height cells arranged in the second row R2 may have a second height H2 in the Y-axis direction, and the multi-height cells continuously arranged in the first row R1 and the second row R2 may have a height corresponding to a sum of heights H1 and H2 in the Y-axis direction.

In some embodiments, the first height H1 of the first row R1 and the second height H2 of the second row R2 may be the same or different from each other. For example, as shown in FIG. 2A, the second height H2 may be greater than the first height H1 (H2>H1). Rows having different heights may be variously arranged. For example, rows with the first height H1 and rows with the second height H2 may be alternately arranged in a ratio of 1:1, 2:2, 4:4, etc.

Patterns for supplying power to cells may be arranged on the boundaries of rows. For example, as shown in FIG. 2A, first to third metal patterns M21 to M23 may extend in the X-axis direction on the boundaries of the first row R1 and the second row R2. A negative supply voltage VSS may be applied to the first and third metal patterns M21 and M23, and n-channel field effect transistors (NFETs) may be arranged adjacent to the first and third metal patterns M21 and M23. In addition, a positive supply voltage VDD may be applied to the second metal pattern M22, and a p-channel field effect transistor (PFET) may be arranged adjacent to the second metal pattern M22.

The integrated circuit may include active patterns extending in the X-axis direction, and a cell may include a transistor formed by an active pattern. For example, as illustrated in FIG. 2A, the integrated circuit 20a may include, in the first row R1, a plurality of first active patterns A11 to A13 overlapping each other in the X-axis direction and a plurality of second active patterns A21 to A23 overlapping each other in the X-axis direction. In addition, the integrated circuit 20a may include, in the second row R2, a plurality of third active patterns A3 to A33 overlapping each other in the X-axis direction and a plurality of fourth active patterns A41 to A43 overlapping each other in the X-axis direction. As shown in FIG. 2A, the plurality of first active patterns A11 to A13 and the plurality of fourth active patterns A41 to A43 adjacent to the first and third metal patterns M21 and M23 to which a negative supply voltage VSS is applied may form an n-channel field effect transistor (NFET), while the plurality of second active patterns A21 to A23 and the plurality of second active patterns A31 to A33 adjacent to the second metal pattern M22 to which a positive supply voltage VDD is applied may form a p-channel field effect transistor (PFET).

In some embodiments, the transition of the active pattern may be limited to a predefined size. For example, as shown in FIG. 2A, the transition of the active patterns in the plurality of first active patterns A11 to A13 in the first row R1 may be limited to a first offset OS1. Accordingly, a difference between widths of the first active patterns A11 and A12 adjacent to each other may correspond to the first offset OS1, and a difference between widths of the first active patterns A12 and A13 adjacent to each other may also correspond to the first offset OS1. In addition, the transition of the active patterns in the plurality of second active patterns A21 to A23 in the first row R1 may be limited to a second offset OS2. In some embodiments, the first offset OS1 and the second offset OS2 may be the same. Similarly, the transition of the active patterns in the plurality of third active patterns A31 to A33 in the second row R2 may be limited to a third offset OS3, and the transition of the active patterns in the plurality of fourth active patterns A41 to A43 in the second row R2 may be limited to a fourth offset OS4. In some embodiments, the third offset OS3 and the fourth offset OS4 may be the same. The first to fourth offsets OS1 to OS4 may be defined by a semiconductor process for manufacturing the integrated circuit 20a, and accordingly, an error caused by an excessive transition of the active patterns in the integrated circuit 20a may be eliminated.

In some embodiments, widths of active patterns in the first row R1 and widths of active patterns in the second row R2 may be different. For example, the maximum width (or minimum width) of the plurality of first active patterns A11 to A13 in the first row R1 may be different from the maximum width (or minimum width) of the plurality of fourth active patterns A41 to A43 in the second row R2. In addition, the maximum width (or minimum width) of the plurality of second active patterns A21 to A23 in the first row R1 may be different from the maximum width (or minimum width) of the plurality of third active patterns A31 to A33 in the second row R2. The maximum width of active patterns may refer to a widest width of the active patterns. Accordingly, the maximum width of the first active patterns A11 to A13 may be a width of the first active pattern A13, and the maximum width of the second active patterns A21 to A23 may be a width of the second active pattern A23. Further, the minimum width of active patterns may refer to a narrowest width of the active patterns. Accordingly, the minimum width of the first active patterns A11 to A13 may be a width of the first active pattern A11, and the minimum width of the second active patterns A21 to A23 may be a width of the second active pattern A21.

Referring to FIG. 2B, the active pattern in the integrated circuit 20b may have one of two widths. For example, as shown in FIG. 2B, each of the plurality of first active patterns A11 to A13 overlapping each other in the X-axis direction in the first row R1 may have one of two widths W11 and W12 having a difference by the first offset OS1. In addition, each of the plurality of second active patterns A21 to A23 overlapping each other in the X-axis direction in the first row R1 may have one of two widths W21 and W22 having a difference by the second offset OS2. In some embodiments, the first offset OS1 and the second offset OS2 may be the same. In some embodiments, widths W11 and W12 of the plurality of first active patterns A11 to A13 may be the same as widths W21 and W22 of the plurality of second active patterns A21 to A23, respectively. Similarly, in the second row, each of the plurality of third active patterns A31 to A33 overlapping each other in the X-axis direction may have one of two widths W31 and W32 having a difference by the third offset OS3, and each of the plurality of fourth active patterns A41 to A43 overlapping each other in the X-axis direction may have one of two widths W41 and W42 having a difference by the fourth offset OS4. In some embodiments, the third offset OS3 and the fourth offset OS4 may be the same. In some embodiments, widths W31 and W32 of the plurality of third active patterns A31 to A33 may be the same as widths W41 and W42 of the plurality of fourth active patterns A41 to A43, respectively.

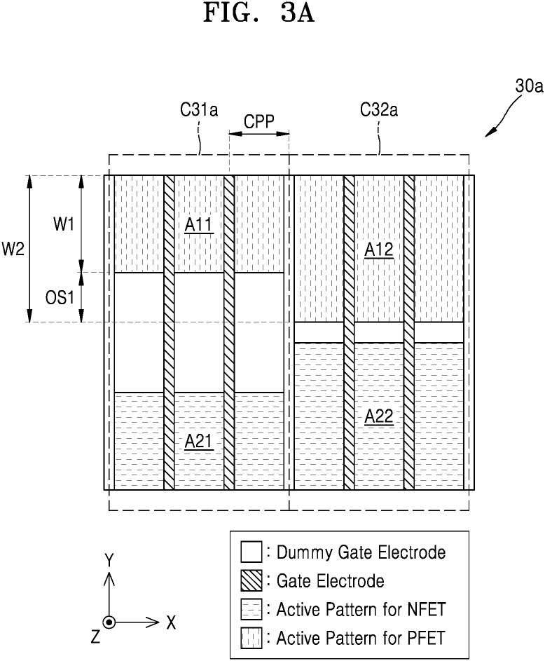

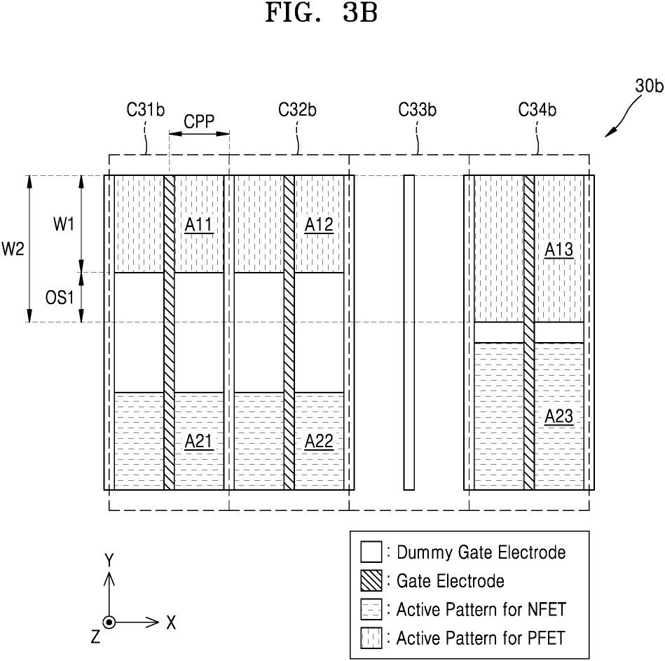

FIGS. 3A and 3B are plan views illustrating layouts of an integrated circuit according to example embodiments. In some embodiments, the cell may be terminated by a diffusion break, and the transition of the active pattern may occur in the diffusion break. In some embodiments, the active pattern in the cell may have a constant width. For example, as shown in FIGS. 3A and 3B, the active pattern may have a constant width within the cell while having different widths in different cells. Hereinafter, the redundant description of FIGS. 3A and 3B will be omitted.

Referring to FIG. 3A, the integrated circuit 30a may include a first cell C31a and a second cell C32a. The first cell C31a may include active patterns A11 and A21 extending in the X-axis direction and gate electrodes extending in the Y-axis direction. The second cell C32a may include active patterns A12 and A22 extending in the X-axis direction and gate electrodes extending in the Y-axis direction. The gate electrodes may extend in the Y-axis direction with a contacted poly pitch (CPP), and in FIG. 3A, each of the first cell C31a and the second cell C32a may have a length in the X-axis direction in correspondence to three CPPs.

Diffusion breaks may be formed instead of the gate electrodes at boundaries parallel to the Y-axis of the first cell C31a and the second cell C32a, and the first cell C31a and the second cell C32a arranged adjacent to each other may share one diffusion break. As illustrated in FIG. 3A, the diffusion break arranged at a position of the gate electrode may be referred to as a single diffusion break (SDB) or a dummy gate. In some embodiments, unlike the illustration in FIG. 3A, the cell may have boundaries extending in the X-axis direction between the gate electrodes, and a diffusion break formed between the gates of adjacent cells may be referred to as a double diffusion break (DDB).

As illustrated in FIG. 3A, the active pattern A11 for PFET in the first cell C31a may have a first width W1, and the active pattern A12 for PFET in the second cell C32a may have a second width W2. As described above with reference to FIGS. 2A and 2B, the second width W2 may be greater than the first width W1 by the first offset OS1. The width of the active pattern may be changed at a diffusion break between the first cell C31a and the second cell C32a, and the active pattern may be removed from the diffusion break. The active pattern A11 and the active pattern A12 may be spaced apart from each other the X-axis direction, and no active pattern may be provided between the active pattern A11 and the active pattern A12, as illustrated in FIG. 3A. The active pattern A11 and the active pattern A12 may be directly adjacent to each other. The term “directly adjacent” as used herein includes configurations where two “elements” (e.g., the active patterns A11 and A12) which are said to be directly adjacent to one another are positioned so that no other like element is located between the two elements which are said to be directly adjacent to one another.

Referring to FIG. 3B, the integrated circuit 30b may include first to fourth cells C31b to C34b. The first cell C31b may include active patterns A11 and A21 extending in the X-axis direction and a gate electrode extending in the Y-axis direction. The second cell C32b may include active patterns A12 and A22 extending in the X-axis direction and a gate electrode extending in the Y-axis direction. As illustrated in FIG. 3B, the active pattern A11 of the first cell C31b and the active pattern A12 of the second cell C32b may have the first width W1, and may be separated from each other by an SDB extending in the Y-axis direction between the first cell C31b and the second cell C32b.

The fourth cell C34b may include active patterns A13 and A23 extending in the X-axis direction and a gate electrode extending in the Y-axis direction. The second width W2 of the active pattern A13 of the fourth cell C34b may be greater than the first width W1 of the active pattern A12 of the second cell C32b by the first offset OS1. Unlike the integrated circuit 30a of FIG. 3A, the transition of the active pattern in the integrated circuit 30b of FIG. 3B may require a diffusion break extending in the Y-axis direction by a width of a CPP or more. Accordingly, the integrated circuit 30b may include the third cell C33b between the second cell C32b and the fourth cell C34b, and the active patterns may be removed from the third cell C33b. In some embodiments, the third cell C33b may not include any active pattern. Herein, a cell including a transistor (or an active pattern) and designed to perform a function by the transistor, such as the first cell C31b, the second cell C32b, and the fourth cell C34b, may be referred to as a function cell. In addition, as shown in the third cell C33b, the cell inserted between the functional cells for the transition of the active pattern may be referred to as a filler cell. In some embodiments, unlike the illustration in FIG. 3B, the filler cell may correspond to one CPP (1CPP) or have a length in the X-axis direction exceeding two CPPs (2CPP).

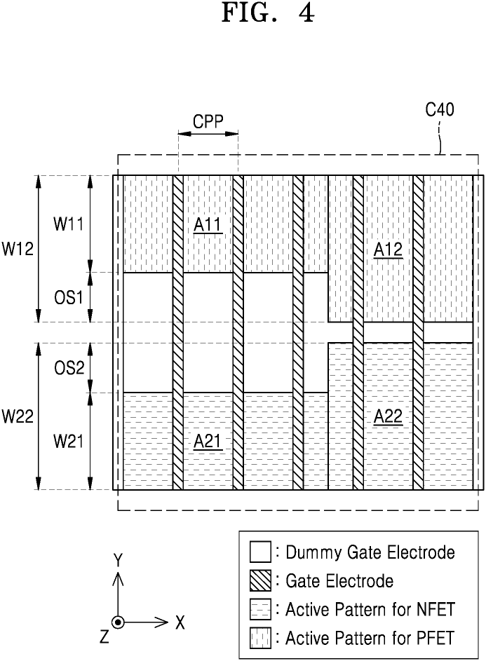

FIG. 4 is a plan view illustrating a layout of a cell according to an example embodiment. In some embodiments, the transition of the active pattern may occur in the cell.

Referring to FIG. 4, the cell C40 may include active patterns A11 and A12 overlapping each other in the X-axis direction and active patterns A21 and A22 overlapping each other in the X-axis direction. The width W12 of the active pattern A12 may be greater than the width W11 of the active pattern A11 by the first offset OS1, and the width W22 of the active pattern A22 may be greater than the width W21 of the active pattern A21 by the second offset OS2. The first offset OS1 and the second offset OS2 may be defined by a semiconductor process, and the cell C40 may be designed to include a transition of an active pattern corresponding to the first offset OS1 or the second offset OS2. Accordingly, the cell C40 may be designed to have optimized performance and efficiency, and an error caused by the cell C40 may be reduced or prevented.

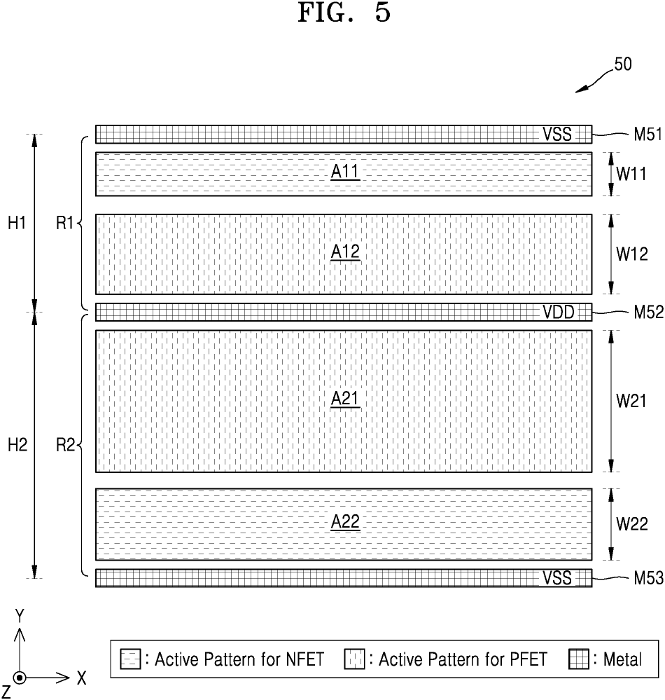

FIG. 5 is a plan view illustrating a layout of an integrated circuit 50 according to an example embodiment. As described above with reference to FIGS. 2A and 2B, the integrated circuit 50 may include a plurality of cells, and the plurality of cells may be arranged in rows extending in the X-axis direction, for example, the first row R1 and/or the second row R2. As described above with reference to FIGS. 2A and 2B, the first height H1 of the first row R1 and the second height H2 of the second row R2 may be the same or different from each other.

In some embodiments, the width of the active pattern for the NFET and the width of the active pattern for the PFET in the cell may be different from each other. For example, as illustrated in FIG. 5, the active pattern A11 for the NFET and the active pattern A12 for the PFET may extend in the X-axis direction in the first row R1. The width W11 of the active pattern A11 for the NFET may be less than the width W12 of the active pattern A12 for the PFET (W11<W12). In some embodiments, unlike the illustration in FIG. 5, the width W11 of the active pattern A11 for the NFET may be greater than the width W12 of the active pattern A12 for the PFET (W11>W12). In addition, as shown in FIG. 5, the active pattern A21 for the PFET and the active pattern A22 for the NFET may extend in the X -axis direction in the second row R2. The width W21 of the active pattern A21 for the PFET may be greater than the width W22 of the active pattern A22 for the NFET (W21>W22). In some embodiments, unlike the illustration in FIG. 5, the width W21 of the active pattern A21 for the PFET may be less than the width W22 of the active pattern A22 for the NFET (W21<W22).

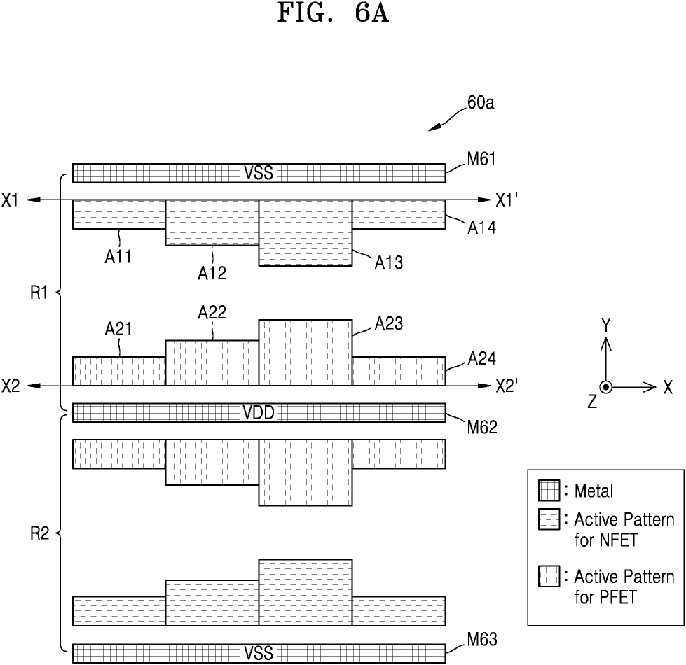

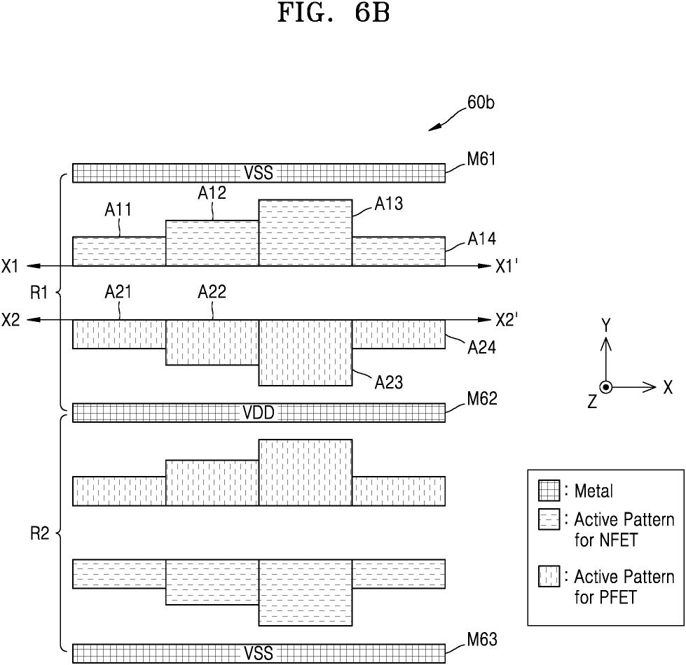

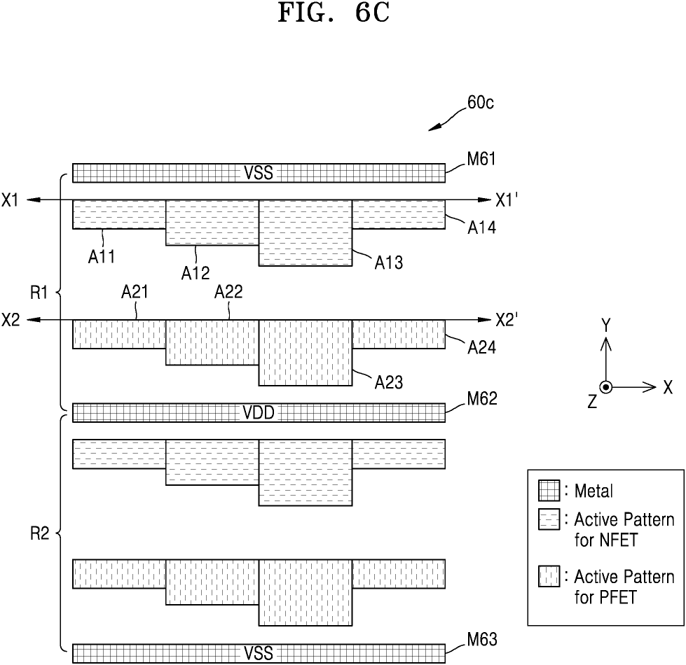

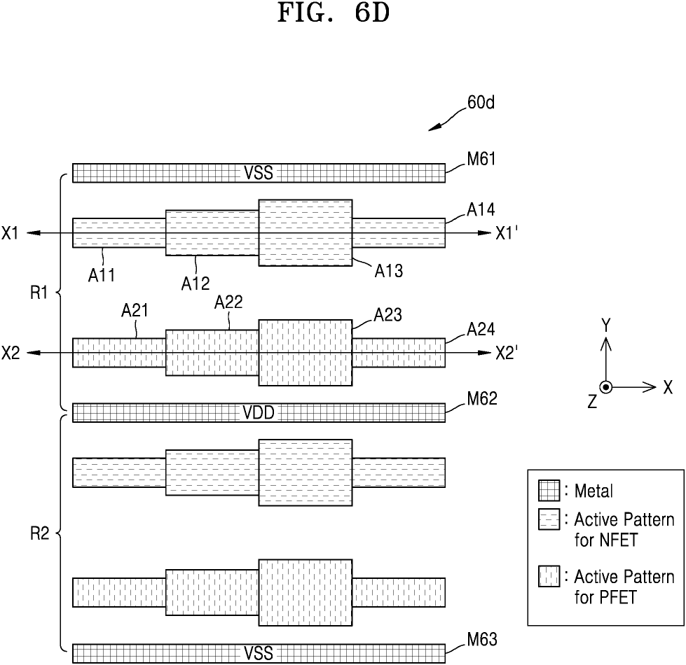

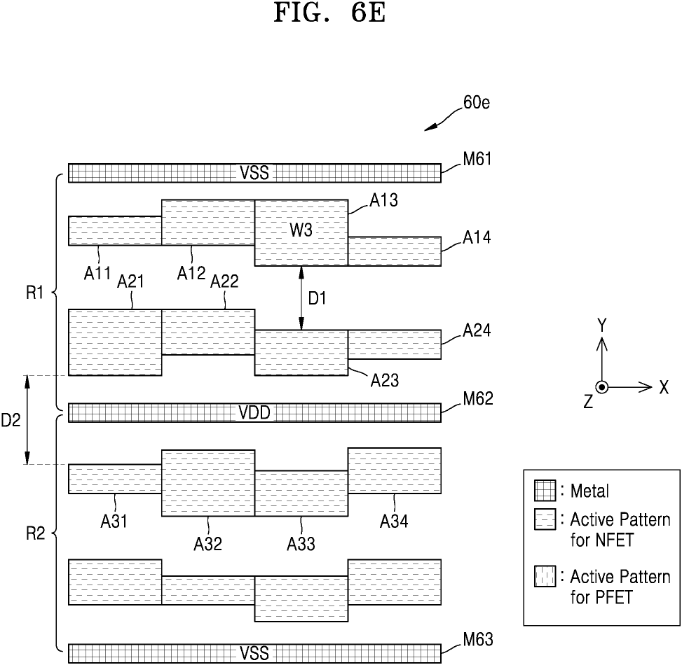

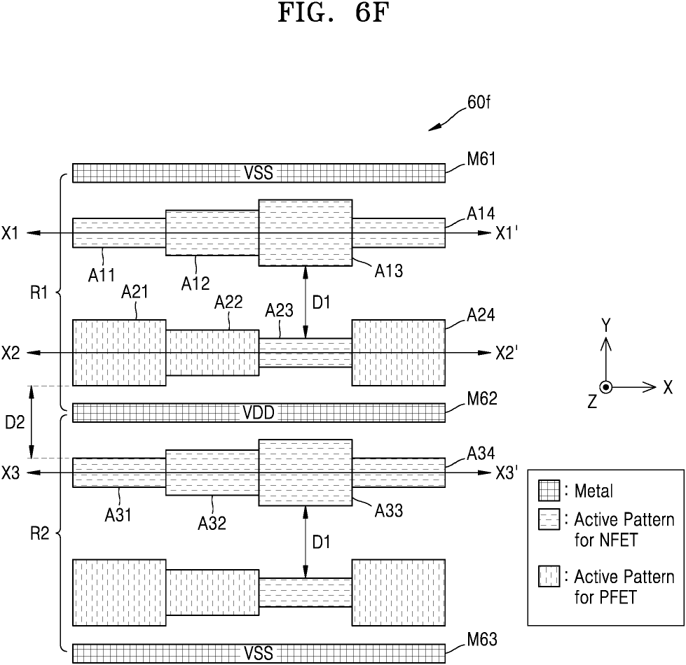

FIGS. 6A to 6F are plan views illustrating layouts of an integrated circuit according to example embodiments. The plan views of FIGS. 6A to 6F illustrate examples in which active patterns having different widths are variously aligned. In FIGS. 6A to 6F, each of the integrated circuits 60a to 60f may include first to third metal patterns M61 to M63 extending in the X-axis direction on the boundaries of the first row R1 and the second row R2. A negative supply voltage VSS may be applied to the first and third metal patterns M61 and M63, and a positive supply voltage VDD may be applied to the second metal pattern M62.

Referring to FIG. 6A, the integrated circuit 60a may include active patterns extending in the X-axis direction in the first row R1 and the second row R2. For example, in the first row R1, the integrated circuit 60a may include the plurality of first active patterns A11 to A14 overlapping each other in the X-axis direction, and may include the plurality of second active patterns A21 to A24 overlapping each other in the X-axis direction. In some embodiments, the transition of the active pattern may support two offsets. For example, the offset between the adjacent active patterns A11 and A12 may be the same as the offset between the adjacent active patterns A12 and A13 and may be different from the offset between the adjacent active patterns A13 and A14.

In some embodiments, the active patterns may have boundaries overlapping a line extending in the X-axis direction. For example, as illustrated in FIG. 6A, the plurality of first active patterns A11 to A14 may have boundaries overlapping line X1-X1′ extending in the X-axis direction, and the plurality of second active patterns A21 to A24 may have boundaries overlapping line X2-X2′ extending in the X-axis direction. As illustrated in FIG. 6A, the line X1-X1′ and the line X2-X2′ may be adjacent to the boundaries of the first row R1, and thus the plurality of first active patterns A11 to A14 and the plurality of second active patterns A21 to A24 may be arranged between the line X1-X1′ and the line X2-X2′. The plurality of first active patterns A11 to A14 may include respective side surfaces (also referred to as first outer side surfaces) aligned in the X-axis direction, and the plurality of second active patterns A21 to A24 may include respective side surfaces (also referred to as second outer side surfaces) aligned in the X-axis direction, as illustrated in FIG. 6A. The plurality of first active patterns A11 to A14 may also include first inner side surfaces facing the plurality of second active patterns A21 to A24, and the plurality of second active patterns A21 to A24 may also include second inner side surfaces facing the plurality of first active patterns A11 to A14.

Referring to FIG. 6B, the integrated circuit 60b may include active patterns extending in the X-axis direction in the first row R1 and the second row R2. For example, in the first row R1, the integrated circuit 60b may include the plurality of first active patterns A11 to A14 overlapping each other in the X-axis direction, and may include the plurality of second active patterns A21 to A24 overlapping each other in the X-axis direction. In some embodiments, the transition of the active pattern may support two offsets. For example, the offset between the adjacent active patterns A11 and A12 may be the same as the offset between the adjacent active patterns A12 and A13 and may be different from the offset between the adjacent active patterns A13 and A14.

In some embodiments, the active patterns may have boundaries overlapping a line extending in the X-axis direction. For example, as illustrated in FIG. 6B, the plurality of first active patterns A11 to A14 may have boundaries overlapping line X1-X1′ extending in the X-axis direction, and the plurality of second active patterns A21 to A24 may have boundaries overlapping line X2-X2′ extending in the X-axis direction. As illustrated in FIG. 6B, the line X1-X1′ and the line X2-X2′ may be adjacent to the center of the first row R1, and thus the line X1-X1′ and the line X2-X2′ may extend in the X-axis direction between the plurality of first active patterns A11 to A14 and the plurality of second active patterns A21 to A24. The plurality of first active patterns A11 to A14 may include first inner side surfaces that are aligned in the X-axis direction and face the plurality of second active patterns A21 to A24, and the plurality of second active patterns A21 to A24 may include second inner side surfaces that are aligned in the X-axis direction and face the plurality of first active patterns A11 to A14, as illustrated in FIG. 6B.

Referring to FIG. 6C, the integrated circuit 60c may include active patterns extending in the X-axis direction in the first row R1 and the second row R2. For example, in the first row R1, the integrated circuit 60c may include the plurality of first active patterns A11 to A14 overlapping each other in the X-axis direction, and may include the plurality of second active patterns A21 to A24 overlapping each other in the X-axis direction. In some embodiments, the transition of the active pattern may support two offsets. For example, the offset between the adjacent active patterns A11 and A12 may be the same as the offset between the adjacent active patterns A12 and A13 and may be different from the offset between the adjacent active patterns A13 and A14.

In some embodiments, the active patterns may have boundaries overlapping a line extending in the X-axis direction. For example, as illustrated in FIG. 6C, the plurality of first active patterns A11 to A14 may have boundaries overlapping line X1-X1′ extending in the X-axis direction, and the plurality of second active patterns A21 to A24 may have boundaries overlapping line X2-X2′ extending in the X-axis direction. As illustrated in FIG. 6C, the line X1-X1′ may be adjacent to the boundary of the first row R1, while the line X2-X2′ may be adjacent to the center of the first row R1. Accordingly, the plurality of first active patterns A11 to A14 may be arranged between lines X1-X1′ and X2-X2′, and the line X2-X2′ may extend in the X-axis direction between the plurality of first active patterns A11 to A14 and the plurality of second active patterns A21 to A24. The plurality of first active patterns A11 to A14 may include first outer side surfaces that are aligned in the X-axis direction and may include first inner side surfaces that face the plurality of second active patterns A21 to A24, and the plurality of second active patterns A21 to A24 may include second inner side surfaces that are aligned in the X-axis direction and face the plurality of first active patterns A11 to A14, as illustrated in FIG. 6C.

Referring to FIG. 6D, the integrated circuit 60d may include active patterns extending in the X-axis direction in the first row R1 and the second row R2. For example, in the first row R1, the integrated circuit 60d may include the plurality of first active patterns A11 to A14 overlapping each other in the X-axis direction, and may include the plurality of second active patterns A21 to A24 overlapping each other in the X-axis direction. In some embodiments, the transition of the active pattern may support two offsets. For example, the offset between the adjacent active patterns A11 and A12 may be the same as the offset between the adjacent active patterns A12 and A13 and may be different from the offset between the adjacent active patterns A13 and A14.

In some embodiments, the center (e.g., a center point in the Y-axis direction) of each of the active patterns may be aligned to overlap the line extending in the X-axis direction. For example, as illustrated in FIG. 6D, the center of each of the first active patterns A11 to A14 may be aligned to overlap the line X1-X1′ extending in the X-axis direction, and the center of each of the plurality of second active patterns A21 to A24 may be aligned to overlap the line X2-X2′ extending in the X-axis direction. The first active patterns A11 to A14 may include respective center points in the Y-axis direction, and those center points of the first active patterns A11 to A14 are aligned in the X-axis direction. The second active patterns A21 to A24 may include respective center points in the Y-axis direction, and those center points of the second active patterns A21 to A24 are aligned in the X-axis direction, as illustrated in FIG. 6D.

Referring to FIG. 6E, the integrated circuit 60e may include active patterns extending in the X-axis direction in the first row R1 and the second row R2. For example, in the first row R1, the integrated circuit 60e may include the plurality of first active patterns A11 to A14 overlapping each other in the X-axis direction, and may include the plurality of second active patterns A21 to A24 overlapping each other in the X-axis direction. In addition, the integrated circuit 60e may include a plurality of third active patterns A31 to A34 overlapping each other in the X-axis direction in the second row R2. In some embodiments, the transition of the active pattern may support two offsets. For example, the offset between the adjacent active patterns A11 and A12 may be the same as the offset between the adjacent active patterns A12 and A13 and may be different from the offset between the adjacent active patterns A13 and A14.

In some embodiments, the active patterns may be arranged and may have widths to have a constant distance from the adjacent active patterns in the Y-axis direction. For example, as shown in FIG. 6E, in the first row R1, the plurality of first active patterns A11 to A14 may be spaced apart from the plurality of corresponding second active patterns A21 to A24 by a first distance D1, respectively. In addition, the plurality of second active patterns A21 to A24 in the first row may be spaced apart from the plurality of corresponding third active patterns A31 to A34 by a second distance D2, respectively. The first distance D1 and the second distance D2 may be the same or different from each other.

Referring to FIG. 6F, the integrated circuit 60f may include active patterns extending in the X-axis direction in the first row R1 and the second row R2. For example, in the first row R1, the integrated circuit 60f may include the plurality of first active patterns A11 to A14 overlapping each other in the X-axis direction, and may include the plurality of second active patterns A21 to A24 overlapping each other in the X-axis direction. In addition, the integrated circuit 60f may include a plurality of third active patterns A31 to A34 overlapping each other in the X-axis direction in the second row R2. In some embodiments, the transition of the active pattern may support two offsets. For example, the offset between the adjacent active patterns A11 and A12 may be the same as the offset between the adjacent active patterns A12 and A13 and may be different from the offset between the adjacent active patterns A13 and A14.

In some embodiments, the center (e.g., a center point in the Y-axis direction) of each of the active patterns may be aligned to overlap the line extending in the X -axis direction. For example, as illustrated in FIG. 6F, the center of each of the first active patterns A11 to A14 may be aligned to overlap the line X1-X1′ extending in the X-axis direction, the center of each of the plurality of second active patterns A21 to A24 may be aligned to overlap the line X2-X2′ extending in the X-axis direction, and the center of each of the plurality of third active patterns A31 to A34 may be aligned to overlap the line X3-X3′ extending in the X-axis direction.

In some embodiments, each of the active patterns may have a width to have a constant distance from the adjacent active pattern in the Y-axis direction. For example, as shown in FIG. 6F, in the first row R1, the plurality of first active patterns A11 to A14 may be spaced apart from the plurality of corresponding second active patterns A21 to A24 by a first distance D1, respectively. In addition, the plurality of second active patterns A21 to A24 in the first row R1 may be spaced apart from the plurality of corresponding third active patterns A31 to A34 by a second distance D2, respectively. The first distance D1 and the second distance D2 may be the same or different from each other.

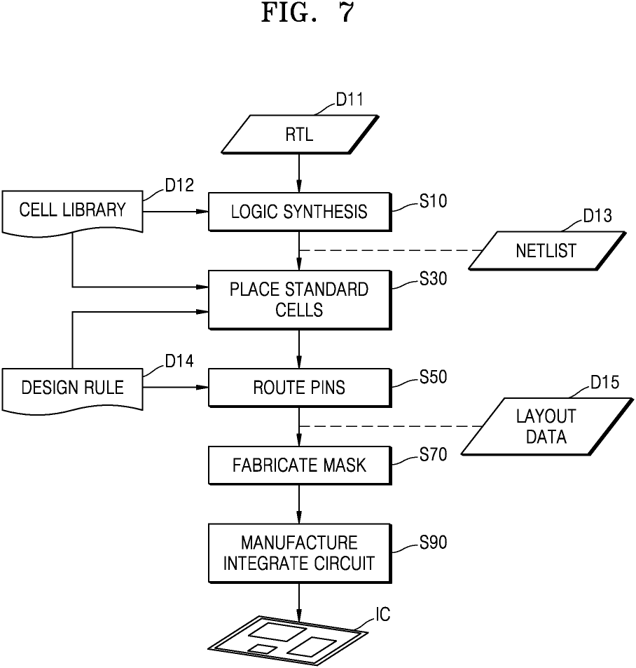

FIG. 7 is a flowchart illustrating a method of manufacturing an integrated circuit (IC) according to an example embodiment. For example, the flowchart of FIG. 7 illustrates an example of a method of manufacturing an integrated circuit (IC) including standard cells. As illustrated in FIG. 7, the method of manufacturing the integrated circuit (IC) may include multiple operations S10, S30, S50, S70 and S90.

A cell library (or standard cell library) D12 may include information on standard cells, for example, information on functions, characteristics, layouts, and the like. In some embodiments, the cell library D12 may define standard cells each including active patterns of different widths. In some embodiments, the cell library D12 may define standard cells including active patterns which have widths being changed. In some embodiments, the cell library D12 may define filler cells inserted for transition of the active pattern. In some embodiments, the cell library D12 may define standard cells including an active pattern for a PFET and an active pattern for a NFET, respectively, the standard cells having different widths.

A design rule D14 may include requirements to be complied with by the layout of the integrated circuit IC. For example, the design rule D14 may include requirements for a space between patterns in the same layer, a minimum width of a pattern, a routing direction of a wiring layer, and the like. In some embodiments, the design rule D14 may define the minimum separation distance in the same track of the wiring layer.

In operation S10, a logic synthesis operation of generating a netlist D13 from register transfer level (RTL) data D11 may be performed. For example, a semiconductor design tool (e.g., a logic synthesis tool) may perform a logic synthesis on the RTL data D11, which is written as a hardware description language (HDL), such as VHSIC Hardware Description Language (VHDL) and Verilog with reference to the cell library D12, and generate a netlist D13 including a bitstream or netlist. The netlist D13 may correspond to an input of place and routing, which will be described below.

In operation S30, cells may be arranged. For example, the semiconductor design tool (e.g., the P&R tool) may arrange standard cells used in the netlist D13 with reference to the cell library D12 and the design rule D14. In some embodiments, the design rule D14 may define the transition of the active pattern allowed in one row. For example, the design rule D14 may define at least one offset allowed in one row, and the adjacent active patterns may have the same width or widths that are different by at least one offset defined by the design rule D14. The semiconductor design tool may select a standard cell including an active pattern having an appropriate width from the cell library D12 in consideration of adjacent standard cells, and may arrange the selected standard cell.

In operation S50, pins of cells may be routed. For example, the semiconductor design tool may generate interconnections that electrically connect output pins and input pins of placed standard cells, and may generate layout data D15 that define placed standard cells and generated interconnections. Each of the interconnections may include a via of a via layer and/or a pattern of a wiring layer. The layout data D15 may have a format, such as a graphic design system-II (GDSII), for example, and may include geometric information of cells and interconnections. The semiconductor design tool may refer to the design rule D14 while routing pins of cells. The layout data D15 may correspond to an output of place and routing. Operation S50 alone or operations S30 and S50 collectively may be referred to as a method of designing an integrated circuit.

In operation S70, an operation of fabricating a mask may be performed. For example, optical proximity correction (OPC) for correcting distortion, such as refraction due to light characteristics in photolithography may be applied to layout data D15. Patterns on the mask may be defined to form patterns arranged on a plurality of layers based on data to which the OPC is applied, and at least one mask (or photomask) for forming patterns of each of the plurality of layers may be fabricated. In some embodiments, the layout of the integrated circuit (IC) may be limitedly changed in operation S70, and the limited change of the integrated circuit IC in operation S70 may be referred to as design policing as a post-processing for optimizing the structure of the integrated circuit (IC).

In operation S90, an operation of fabricating the integrated circuit (IC) may be performed. For example, the integrated circuit (IC) may be manufactured by patterning a plurality of layers using at least one mask fabricated in operation S70. A front-end-of-line (FEOL) may include, for example, the operations of: planarizing and cleaning a wafer; forming a trench; forming a well; forming a gate electrode; and forming a source and a drain. By the FEOL, individual devices, such as transistors, capacitors, resistors, and the like, may be formed on a substrate. In addition, a back-end-of-line (BEOL) may include, for example, the operations of: silicideizing gate, source, and drain regions; adding a dielectric; performing planarization; forming a hole, adding a metal layer; forming a via; forming a passivation layer, and the like. By the BEOL, individual devices, such as transistors, capacitors, resistors, and the like may be interconnected. In some embodiments, a middle-of-line (MOL) may be carried out between the FEOL and the BEOL, and contacts may be formed on individual devices. Then, the integrated circuit (IC) may be packaged in a semiconductor package and may be used as a component of various applications.

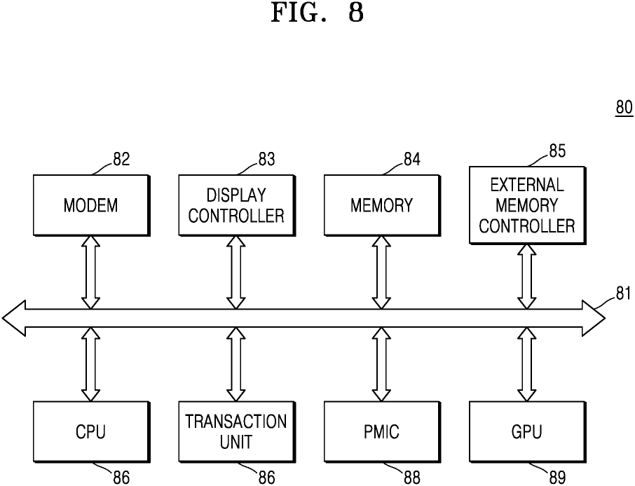

FIG. 8 is a block diagram illustrating a system-on-chip (SoC) 80 according to an example embodiment. The system-on-chip 80 is a semiconductor device and may include an integrated circuit according to an example embodiment. The system-on-chip 80 implements, in one chip, complex blocks, such as intellectual property (IP) performing various functions, and the system-on-chip 80 may be designed by a method of designing an integrated circuit according to example embodiments, and thus the system-on-chip 80 may provide high yield and reliability, and have good (e.g., optimal or highest) performance and efficiency. Referring to FIG. 8, the system-on-chip 80 may include a modem 82, a display controller 83, a memory 84, an external memory controller 85, a central processing unit 86 (CPU), a transaction unit 87, a power management IC (PMIC) 88, and a graphical processing unit (GPU) 89. The respective functional blocks of the system-on-chip 80 may communicate with each other through a system bus 81.

The CPU 86 capable of controlling the operation of the system-on-chip 80 at the highest level may control the operation of other functional blocks 82 to 85 and 87 to 89. The modem 82 may demodulate a signal received from the outside of the system-on-chip 80, or modulate a signal generated inside the system-on-chip 80 to transmit the signal to the outside. The external memory controller 85 may control an operation of transmitting and receiving data from an external memory device connected to the system-on-chip 80. For example, programs and/or data stored in the external memory device may be provided to the CPU 86 or the GPU 89 under the control of the external memory controller 85. The GPU 89 may execute program instructions related to graphic processing. The GPU 89 may receive graphic data through the external memory controller 85, or may transmit the graphic data processed by the GPU 89 to the outside of the system-on-chip 80 through the external memory controller 85. The transaction unit 87 may monitor data transactions of each functional block, and the PMIC 88 may control power supplied to each functional block under the control of the transaction unit 87. The display controller 83 may transmit data generated inside the system-on-chip 80 to the display by controlling a display (or a display device) outside the system-on-chip 80. The memory 84 may include a nonvolatile memory, such as an electrically erasable programmable read-only memory (EEPROM), a flash memory, or the like, or may include a volatile memory, such as a dynamic random access memory (DRAM), a static random access memory (SRAM), or the like.

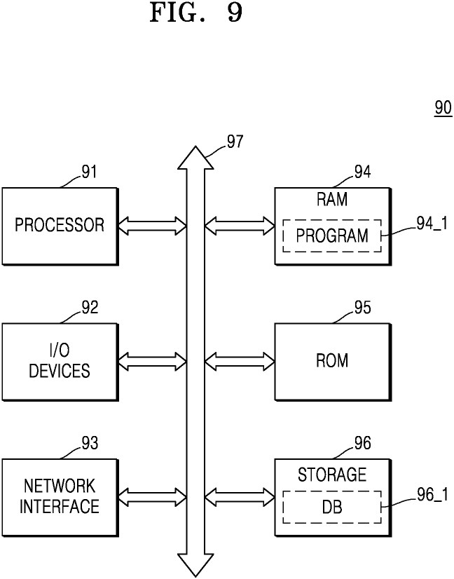

FIG. 9 is a block diagram illustrating a computing system 90 including a memory for storing a program according to an example embodiment. The method of designing an integrated circuit according to example embodiments, for example, at least some of the operations of the flowchart described above, may be performed in the computing system (or computer) 90.

The computing system 90 may be a fixed computing system, such as a desktop computer, a workstation, a server, or the like, or may be a portable computing system, such as a laptop computer, etc. As illustrated in FIG. 9, the computing system 90 may include a processor 91, input/output device 92, a network interface 93, a random access memory (RAM) 94, a read only memory (ROM) 95, and a storage 96. The processor 91, the input/output device 92, the network interface 93, the RAM 94, the ROM 95, and the storage 96 may be connected to a bus 97, and may communicate with each other through the bus 97.

The processor 91 may be referred to as a processing unit, and may include at least one core that may execute any instruction set (for example, Intel Architecture-32 (IA-32), 64-bit expansion IA-32, x86-64, PowerPC, Sparc, MIPS, ARM, IA-64, etc.), such as, for example, a microprocessor, an application processor (AP), a digital signal processor (DSP), and a graphic processing unit. For example, the processor 91 may access the memory, that is, the RAM 94 or the ROM 95 through the bus 97, and may execute instructions stored in the RAM 94 or the ROM 95.

The RAM 94 may store a program 94_1 or at least a part thereof for a method of designing an integrated circuit according to an example embodiment, and the program 94_1 may enable the processor 91 to perform the method of designing an integrated circuit, for example, at least some of the operations included in the methods of FIG. 7. That is, the program 94_1 may include a plurality of instructions executable by the processor 91, and the plurality of instructions included in the program 94_1 may enable the processor 91 to perform, for example, at least some of the operations included in the above-described flowcharts.

The storage 96 may not lose the stored data even if the power supplied to the computing system 90 is cut off. For example, the storage 96 may include a nonvolatile memory device, or may include a storage medium, such as a magnetic tape, an optical disk, and a magnetic disk. In addition, the storage 96 may be detachable from the computing system 90. The storage 96 may store the program 94_1 according to an example embodiment, and the program 94_1 or at least a part thereof may be loaded into the RAM 94 from the storage 96 before the program 94_1 is executed by the processor 91. Alternatively, the storage 96 may store a file written in a program language, and the program 94_1 generated from the file by a compiler or the like or at least a part thereof may be loaded into the RAM 94. In addition, as shown in FIG. 9, the storage 96 may store a database (DB) 96_1, and the database 96_1 may include information necessary for designing an integrated circuit, for example, information on the designed blocks, the cell library D12 and/or the design rule D14 of FIG. 7.

The storage 96 may also store data to be processed by the processor 91 or data processed by the processor 91. That is, the processor 91 may generate data by processing data stored in the storage 96 according to the program 94_1, and may enable the storage 96 to store the generated data. For example, the storage 96 may store the RTL data D11, the netlist D13, and/or the layout data D15 of FIG. 7.

The input/output device 92 may include an input device, such as a keyboard and a pointing device, and may include an output device, such as a display device and a printer. For example, a user may trigger execution of the program 94_1 by the processor 91 through the input/output device 92, may input the RTL data D11 and/or the netlist D13 of FIG. 7, and may check the layout data D15 of FIG. 7.

The network interface 93 may provide an access to a network outside the computing system 90. For example, the network may include multiple computing systems and communication links, and the communication links may include wired links, optical links, wireless links, or any other form of links.

It will be understood that, although the terms first, second, and other terms may be used herein to describe various elements, these elements should not be limited by these terms. These terms are only used to distinguish one element from another. For example, a first element may be referred to as a second element, and, similarly a second element may be referred to as a first element without departing from the teachings of the disclosure. As used herein the term “and/or” includes any and all combinations of one or more of the associated listed items.

While the inventive concept has been particularly shown and described with reference to example embodiments thereof, it will be understood that various changes in form and details may be made therein without departing from the scope of the inventive concept. The above-disclosed subject matter is to be considered illustrative, and not restrictive, and the appended claims are intended to cover all such modifications, enhancements, and other embodiments, which fall within the scope of the inventive concept.

What is claimed is:

1. An integrated circuit comprising:
a first active pattern group extending in a first direction in a first row and including a plurality of first active patterns overlapping each other in the first direction, the first row extending in the first direction; and
a plurality of gate electrodes extending in a second direction that is perpendicular to the first direction in the first row,
wherein the plurality of first active patterns comprise any two first active patterns that are adj acent to each other in the first direction, the two first active patterns have first and second widths in the second direction, respectively, and the first and second widths are identical or are different by a first offset or a second offset.

2. The integrated circuit of claim 1, wherein the plurality of gate electrodes extend in the second direction with a first pitch,
the first and second widths are different, and
the two first active patterns are spaced apart from each other by at least the first pitch in the first direction.

3. The integrated circuit of claim 2, wherein no active pattern is between the two first active patterns.

4. The integrated circuit of claim 1, wherein each of the plurality of first active patterns has the first width or the second width that is wider than the first width by the first offset.

5. The integrated circuit of claim 1, wherein
the integrated circuit further comprises a second active pattern group extending in the first direction in a second row that is adjacent to the first row, the second active pattern group including a plurality of second active patterns overlapping each other in the first direction, wherein the first row and the second row have different widths in the second direction.

6. The integrated circuit of claim 5, wherein the plurality of second active patterns comprise any two second active patterns that are adj acent to each other in the first direction and have an identical width in the second direction or have widths in the second direction that are different by a third offset or a fourth offset, and the third offset is different from the first offset and the second offset.

7. The integrated circuit of claim 5, wherein a widest width of the plurality of first active patterns in the second direction is different from a widest width of the plurality of second active patterns in the second direction.

8. The integrated circuit of claim 5, wherein a narrowest width of the plurality of first active patterns in the second direction is different from a narrowest width of the plurality of second active patterns in the second direction.

9. The integrated circuit of claim 1, further comprising a third active pattern group extending in the first direction in the first row and including a plurality of third active patterns overlapping each other in the first direction,
wherein the plurality of third active patterns comprises any two third active patterns that are adjacent to each other in the first direction and have an identical width in the second direction or have widths in the second direction that are different by the first offset or the second offset.

10. The integrated circuit of claim 9, wherein
the plurality of third active patterns comprise respective side surfaces that are aligned in the first direction.

11. The integrated circuit of claim 10, wherein the respective side surfaces of the plurality of first active patterns are first outer side surfaces, and the plurality of first active patterns further comprise respective first inner side surfaces that are opposite to the first outer side surfaces,
the respective side surfaces of the plurality of third active patterns are third outer side surfaces, and the plurality of third active patterns further comprise respective third inner side surfaces that are opposite to the third outer side surfaces, and
the first inner side surfaces face the third inner side surfaces.

12. The integrated circuit of claim 10, wherein the respective side surfaces of the plurality of first active patterns and the respective side surfaces of the plurality of third active patterns are spaced apart from each other in the second direction and face each other.

13. The integrated circuit of claim 10, wherein the respective side surfaces of the plurality of third active patterns face the plurality of first active patterns.

14. The integrated circuit of claim 9, wherein
each of the plurality of first active patterns is spaced apart from a respective one of the plurality of third active patterns by a first distance in the second direction.

15. The integrated circuit of claim 9, wherein the plurality of first active patterns have respective center points aligned in the first direction, and
the plurality of third active patterns have respective center points aligned in the first direction.

16. The integrated circuit of claim 9, wherein
one of the plurality of first active patterns and one of the plurality of third active patterns face each other and have different widths in the second direction.

17. The integrated circuit of claim 1, wherein
each of the plurality of first active patterns comprises at least one nanosheet overlapping at least one of the plurality of gate electrodes in the second direction and a third direction, the third direction being perpendicular to the first direction and the second direction.

18. An integrated circuit comprising a plurality of first functional cells arranged in a first row extending in a first direction,
wherein each of the plurality of first functional cells comprises:
an first active pattern extending in the first direction; and
at least one first gate electrode extending in a second direction perpendicular to the first direction,
wherein the plurality of first functional cells comprise two first functional cells that are adjacent to each other and comprise two first active patterns, respectively, and
the two first active patterns overlap each other in the first direction, have respective widths in the second direction, and the widths of the two first active patterns are identical or are different by a first offset or a second offset.

19. The integrated circuit of claim 18, wherein the widths of the two first active patterns are different, and
the integrated circuit further comprise a filler cell that is between the two first functional cells.

20-27. (canceled)

28. An integrated circuit comprising:
a plurality of cells;
a first pattern and a second pattern, which extend in a first direction, are adjacent to each other and are configured to supply power to first cells among the plurality of cells;
a plurality of first active patterns extending in the first direction between the first pattern and the second pattern and overlapping each other in the first direction; and
a plurality of first gate electrodes extending in a second direction that is perpendicular to the first direction between the first pattern and the second pattern,
wherein the plurality of first active patterns comprise any two first active patterns adjacent to each other in the first direction and have respective widths in the second direction that are identical or different by a first offset or a second offset.

29-42. (canceled)
